(19) United States
(12) Patent Application Publication
(10) Pub. No.: US 2026/0101776 A1
(43) Pub. Date: Apr. 9, 2026

(54) SEMICONDUCTOR PACKAGE

(71) Applicant: Samsung Electronics Co., Ltd., Suwon-si (KR)

(72) Inventors: Junghoon KANG, Suwon-si (KR); Kiju LEE, Suwon-si (KR)

(73) Assignee: Samsung Electronics Co., Ltd., Suwon-si (KR)

(21) Appl. No.: 19/192,611

(22) Filed: Apr. 29, 2025

(30) Foreign Application Priority Data
Oct. 8, 2024 (KR) 10-2024-0136984

(51) Int. Cl. H01L 23/00; H01L 23/498; H01L 23/538; H01L 25/18; H10B 80/00

(52) U.S. Cl. CPC H10W 70/611; H10W 90/401; H10W 90/701; H10B 80/00; H10W 72/222; H10W 72/223; H10W 72/235; H10W 72/255; H10W 90/00; H10W 90/724

(57) ABSTRACT

A semiconductor package may include a first substrate; a second substrate on the first substrate; at least one chip structure on the second substrate; connection bumps below the first substrate; first bump structures between the first substrate and the second substrate; and second bump structures between the at least one chip structure and the second substrate, wherein each of at least a portion of the first bump structures and the each of at least a portion of the second bump structures includes a pillar bump, a solder ball connecting the pillar bump to one of the upper pads or upper terminals, and a barrier film at least partially covering a side surface of the pillar bump, and wherein a thickness of the barrier film decreases in a direction perpendicular to the side surface of the pillar bump in a portion adjacent to the solder ball.

### CROSS-REFERENCE TO RELATED APPLICATION(S)

This application claims benefit of priority to Korean Patent Application No. 10-2024-0136984 filed on Oct. 8, 2024 in the Korean Intellectual Property Office, the disclosure of which is incorporated herein by reference in its entirety.

### BACKGROUND

At least some example embodiments of inventive concepts relate to a semiconductor package, and/or to methods of manufacturing thereof.

In accordance with trends toward miniaturization and high integration density of semiconductor chips, development of bump structures which may be arranged in a fine pitch may be carried out. In the case of a bump structure (e.g., a C2 bump) in which a pillar-shaped bump and a solder ball are combined, it may be advantageous to develop one or more techniques to reduce deviation of solder balls and to reduce, limit, or prevent shorts between bump structures.

### SUMMARY

Various example embodiments relate toa semiconductor package having improved reliability.

According to some example embodiments of inventive concepts, a semiconductor package may include a first substrate including upper pads and lower pads, the upper and lower pads opposite to each other, the first substrate including a first redistribution circuit electrically connecting the upper pads to the lower pads; a second substrate on the first substrate and including upper terminals and lower terminals opposite to each other, the second substrate including a second redistribution circuit connecting the upper terminals to the lower terminals; at least one chip structure on the second substrate and including connection pads; connection bumps below the first substrate; first bump structures between the first substrate and the second substrate and electrically connecting the upper pads of the first substrate to the lower terminals of the second substrate; and second bump structures between the at least one chip structure and the second substrate and electrically connecting the upper terminals of the second substrate to the connection pads of the at least one chip structure, wherein each of at least some of the first bump structures and the second bump structures includes a pillar bump in contact with one of the lower terminals or with the connection pads, a solder ball connecting the pillar bump to one of the upper pads or the upper terminals, and a barrier film at least partially covering a side surface of the pillar bump, and wherein a thickness of the barrier film decreases in a direction perpendicular to the side surface of the pillar bump in a portion that is adjacent to the solder ball.

According to some example embodiments of inventive concepts, a semiconductor package may include a first substrate including a first redistribution circuit; a second substrate on the first substrate and including a second redistribution circuit; at least one chip structure on the second substrate and including connection pads; first bump structures between the first substrate and the second substrate and electrically connecting the first redistribution circuit to the second redistribution circuit; and second bump structures between the at least one chip structure and the second substrate and electrically connecting the second redistribution circuit to the connection pads, wherein each of at least some of the first bump structures and each of at least some of the second bump structures includes a pillar bump, a solder ball on a lower surface of the pillar bump, and a barrier film on a side surface of the pillar bump, wherein the side surface of the pillar bump includes an upper side surface and a lower side surface, the upper side surface in contact with the barrier film, the lower side surface exposed from the barrier film, and wherein the solder ball is in contact with the lower surface of the pillar bump and with the lower side surface of the pillar bump.

According to some example embodiments of inventive concepts, a semiconductor package may include first substrate including a first redistribution circuit; a second substrate on the first substrate and including a second redistribution circuit; at least one chip structure on the second substrate and including connection pads; first bump structures between the first substrate and the second substrate and electrically connecting the first redistribution circuit to the second redistribution circuit; and second bump structures between the at least one chip structure and the second substrate and electrically connecting the second redistribution circuit to the connection pads, wherein each of at least some of the first bump structures and each of at least some of the second bump structures includes a pillar bump, a solder ball at least partially covering a lower surface of the pillar bump, and a barrier film at least partially covering a side surface of the pillar bump, the barrier film includes a first portion and a second portion, the first portion having a first side surface extending along the side surface of the pillar bump, the second portion having a second side surface extending from the first side surface to the side surface of the pillar bump, and a slope of the second side surface with respect to the side surface of the pillar bump decreases towards the solder ball.

According to some example embodiments, a method of manufacturing a bump structure may include forming a plating seed layer on a substrate; forming a mask pattern on the substrate; forming a plating layer in the mask pattern; removing the mask pattern; forming a pillar bump; forming a natural oxide film on the pillar bump; forming a flux layer on the pillar bump; performing a reflow process to activate the flux layer, remove the natural oxide layer, and form a barrier film on the surface of the pilar bump; performing a second reflow process in which a solder ball is attached to the pillar bump.

According to some example embodiments, the method of manufacturing bump structures may further include mounting a chip structure on upper terminals of the substrate.

According to some example embodiments, the method of manufacturing a bump structure may further include forming one or more through-holes in the mask pattern to expose the upper terminals.

According to some example embodiments, in a method of manufacturing a bump structure, the pillar bump may include a seed layer and a plating layer, the seed layer formed by partially etching the plating layer, the plating layer being exposed after the mask pattern is removed.

According to some example embodiments, the method of manufacturing a bump structure may further include converting the natural oxide film into the barrier film and forming a second portion of the barrier film by suppressing formation of the oxide film by the flex layer.

### BRIEF DESCRIPTION OF DRAWINGS

The above and other aspects, features, and advantages of inventive concepts will be more clearly understood from the following detailed description, taken in combination with the accompanying drawings, in which:

FIG. 1A is a cross-sectional diagram illustrating a semiconductor package according to some example embodiments of inventive concepts;

FIG. 1B is a plan diagram taken along line I-I′ in FIG. 1A;

FIGS. 2A to 2E are enlarged diagram illustrating region ‘A’ in FIG. 1A according to some example embodiments and modified example embodiments;

FIGS. 3A to 3F are diagrams illustrating a process of manufacturing a bump structure according to some example embodiments of inventive concepts;

FIGS. 4A and 4B are graphs indicating characteristics of a barrier film included in a semiconductor package according to some example embodiments of inventive concepts;

FIG. 5 is a cross-sectional diagram illustrating a semiconductor package according to some example embodiments of inventive concepts;

FIG. 6 is a cross-sectional diagram illustrating a semiconductor package according to some example embodiments of inventive concepts;

FIG. 7 is a cross-sectional diagram illustrating a semiconductor package according to some example embodiments of inventive concepts; and

FIG. 8 is a cross-sectional diagram illustrating a semiconductor package according to some example embodiments of inventive concepts.

### DETAILED DESCRIPTION

Hereinafter, various example embodiments of inventive concepts will be described as follows with reference to the accompanying drawings.

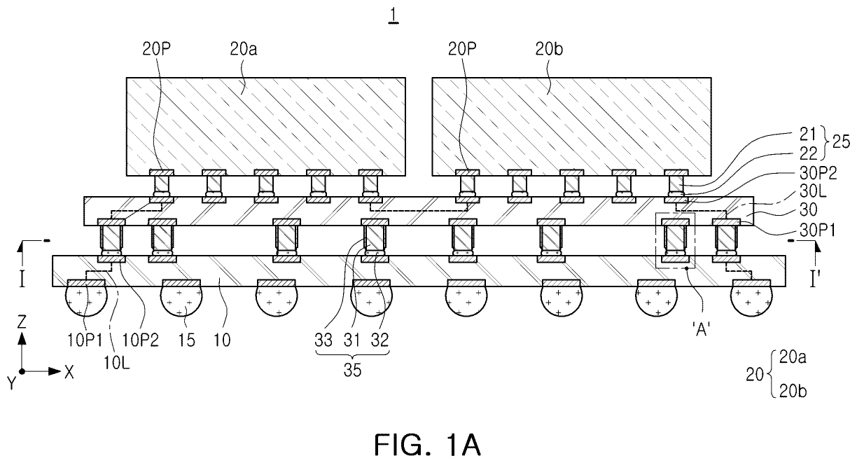

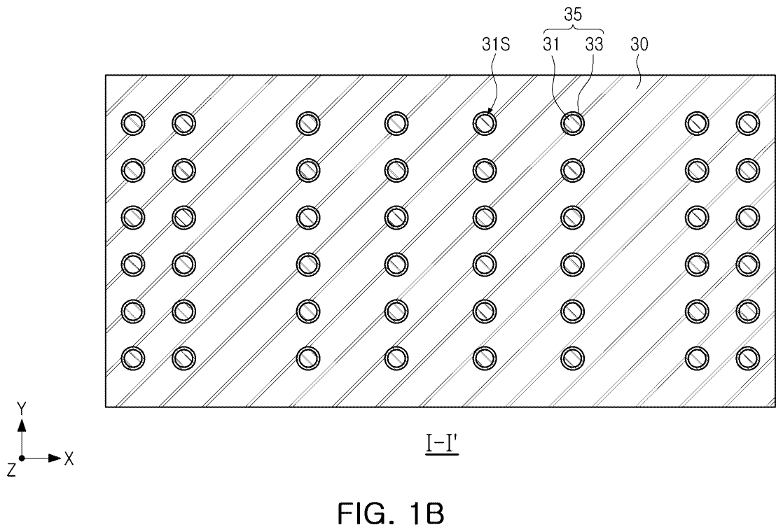

FIG. 1A is a cross-sectional diagram illustrating a semiconductor package according to example embodiments. FIG. 1B is a plan diagram taken along line I-I′ in FIG. 1A.

Referring to FIGS. 1A and 1B, a semiconductor package 1 in some example embodiments may include a first substrate 10, a second substrate 30, at least one chip structure 20, first bump structures 35, and second bump structures 25.

The first substrate 10 may be or include a substrate for a semiconductor package including a printed circuit board (PCB), a ceramic substrate, a glass substrate, a tape interconnection substrate, and/or the like. The first substrate 10 may include lower pads 10P1, upper pads 10P2, and a first redistribution circuit 10L.

The lower pads 10P1 and upper pads 10P2 may be positioned opposite to each other. The lower pads 10P1 may be disposed on a lower surface of the first substrate 110, and the upper pads 10P2 may be disposed on an upper portion of the first substrate 110. The lower pads 10P1 and the upper pads 10P2 may include, for example, at least one metal or an alloy of two or more metals selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), but example embodiments are not limited thereto. The lower pads 10P1 and the upper pads 10P2 may be electrically connected to each other through the first redistribution circuit 10L. The first redistribution circuit 10L may be formed of or include a material similar to a material of the lower pads 10P1 and the upper pads 10P2, but example embodiments are not limited thereto.

The upper pads 10P2 may be connected to the first bump structures 35 disposed between the chip structure 120 and the first substrate 110. The lower pads 10P1 may be connected to connection bumps 150 disposed below the first substrate 10. The connection bumps 150 may be or include solder balls formed of, for example, tin (Sn) or an alloy including tin (Sn), but example embodiments are not limited thereto. In some example embodiments, an underfill layer surrounding the first bump structures 35 may be formed between the first substrate 10 and the second substrate 30.

The second substrate 30 may be, for example, configured as an interposer substrate disposed between the first substrate 10 and the chip structure 20. The second substrate 30 may include lower terminals 30P1, upper terminals 30P2, and a second redistribution circuit 30L.

The lower terminals 30P1 and the upper terminals 30P2 may be positioned opposite to each other. The lower terminals 30P1 and the upper terminals 30P2 may include, for example, at least one metal or an alloy of two or more metals selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), but example embodiments are not limited thereto. The lower terminals 30P1 and the upper terminals 30P2 may be electrically connected to each other through a second redistribution circuit 30L. The second redistribution circuit 30L may be formed of or include a material similar to that of the lower terminals 30P1 and the upper terminals 30P2, but example embodiments are not limited thereto.

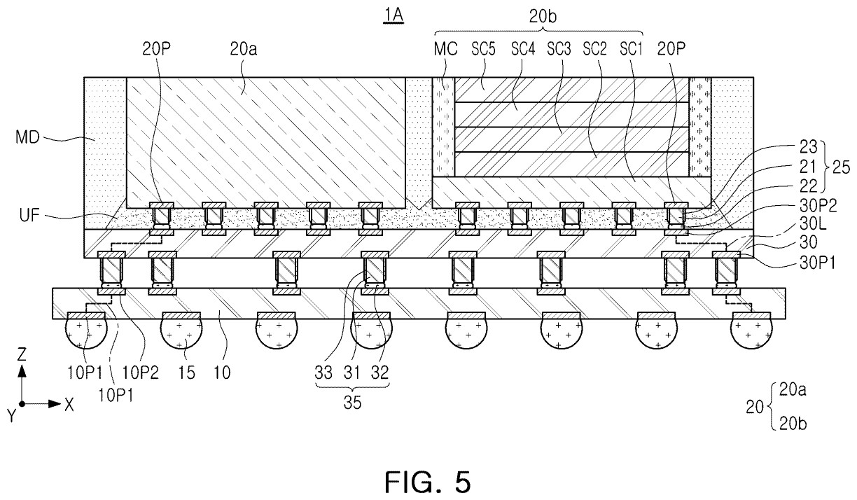

The upper terminals 30P2 may be connected to second bump structures 25 disposed between the chip structure 120 and the second substrate 30. The lower terminals 30P1 may be connected to first bump structures 35 disposed below the second substrate 30. In some example embodiments, the semiconductor package may further include an underfill layer surrounding or at least partially surrounding second bump structures 25 on the second substrate 30, and/or an encapsulation layer covering or at least partially covering the chip structure 20 (see, for example, FIGS. 5 to 8).

The chip structure 20 may include a semiconductor wafer and an integrated circuit (IC) formed of or include a semiconductor element such as, for example, silicon, germanium, or a compound semiconductor such as silicon carbide (SiC), gallium arsenide (GaAs), indium arsenide (InAs), and indium phosphide (InP), but example embodiments are not limited thereto. The chip structure 20 may be configured as a bare semiconductor chip without a bump or an interconnection layer formed therein, but example embodiments thereof are not limited thereto, and the chip structure 20 may also be configured as, for example, a packaged type semiconductor chip.

The chip structure 20 may include a logic chip such as a central processor (CPU), a graphics processor (GPU), a filled programmable gate array (FPGA), an application processor (AP), a digital signal processor, an encryption processor, a microprocessor, a microcontroller, an analog-to-digital converter, an application-specific IC (ASIC), and/or a memory chip including a volatile memory such as a dynamic RAM (DRAM), static RAM (SRAM), and non-volatile memory such as phase change RAM (PRAM), magnetic RAM (MRAM), resistive RAM (RRAM), and flash memory.

The chip structure 20 may be disposed on the second substrate 30. The chip structure 20 may include connection pads 20P for, for example, connecting to an integrated circuit. The connection pads 20P may include, for example, at least one metal or an alloy formed of two or more metals selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), but example embodiments are not limited thereto. The connection pads 20P may be electrically connected to the upper terminals 30P2 of the second substrate 30 through the second bump structures 25.

The chip structure 20 may be provided as a plurality of chip structures 20a and 20b disposed on the second substrate 30. The plurality of chip structures 20a and 20b may be electrically connected to each other through the second redistribution circuit 30L. For example, the plurality of chip structures 20 may include a first chip structure 20a and a second chip structure 20b. The first chip structure 20a and the second chip structure 20b may include different types of semiconductor chips. For example, the first chip structure 20a may include a logic chip such as a central processor (CPU), a graphics processor (GPU), a filled programmable gate array (FPGA), a digital signal processor, an encryption processor, a microprocessor, a microcontroller, an analog-to-digital converter, an ASIC, and/or the like, and the second chip structure 20b may, for example, include a memory chip such as a DRAM, an SRAM, a PRAM, a ReRAM, an FeRAM, an MRAM, and/or a flash memory. In some example embodiments, the second chip structure 20b may be provided as a high-performance memory device such as a high bandwidth memory (HBM) or a hybrid memory cube (HMC) (see FIG. 5), but example embodiments are not limited thereto.

The bump structures 25 and 35 may electrically connect the first substrate 10, the second substrate 30, and the chip structure 20 to each other. The bump structures 25 and 35 may include first bump structures 35 between the first substrate 10 and the second substrate 30, and second bump structures 25 between the second substrate 30 and the chip structure 20. The first bump structures 35 may electrically connect upper pads 10P2 of the first substrate 10 to lower terminals 30P1 of the second substrate 30. The second bump structures 25 may electrically connect upper terminals 30P2 of the second substrate 30 to connection pads 20P of the chip structure 20. Each of the bump structures 25 and 35 may have a size and a pitch finer than those of the connection bumps 15. A minimum distance between (for example, a minimum distance between individual ones of) the first bump structures 25 and a minimum distance between the second bump structures 35 may be smaller than a minimum distance between the connection bumps 15. The minimum distance between the first bump structures 35 and the second bump structures 25 may be, for example, about 100 μm or less, for example, about 20 μm to about 100 μm, about 20 μm to about 80 μm, about 20 μm to about 50 μm, or the like, but example embodiments are not limited thereto. A minimum distance between the first bump structures 35 may be greater than a minimum distance between the second bump structures 25.

According to some example embodiments, at least a portion of the densely arranged bump structures 25 and 35, for example, each of the first bump structures 35 and/or the second bump structures 25, may include a pillar bump, a solder ball, and/or a barrier film. In some example embodiments, by the bump structures 25 and 35 including the pillar bump and the barrier film, shorts between the solder balls 22 and 32 may be limited, reduced, or prevented, and a height deviation between the solder balls 22 and 32 may be reduced. Hereinafter, the first bump structure 35 illustrated to include the barrier film 33 in FIGS. 1A and 1B will be described, but in some example embodiments, the second bump structure 25 may also have a structure including the barrier film (see, for example, FIG. 5).

In some example embodiments, the first bump structures 35 may include a first pillar bump 31, a first solder ball 32, and/or a first barrier film 33, and the second bump structures 25 may include a second pillar bump 21, and/or a second solder ball 22.

The first pillar bump 31 may be in contact with lower terminals 30P1 of the second substrate 30. The first pillar bump 31 may include, for example, at least one metal or an alloy of two or more metals selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), or zinc (Zn), but example embodiments are not limited thereto. The first pillar bump 31 may, for example, have a cylindrical or polygonal pillar shape, but example embodiments are not limited thereto. The second pillar bump 21 may be configured substantially similar to the first pillar bump 31, but example embodiments are not limited thereto.

The first solder ball 32 may be in contact with the first pillar bump 31 and the upper pads 10P2 of the first substrate 10. The first solder ball 32 may be formed of or include tin (Sn) or an alloy including tin (Sn), for example, an alloy including at least two or more of tin (Sn), lead (Pb), silver (Ag), copper (Cu), or bismuth (Bi), but example embodiments are not limited thereto. The second solder ball 22 may be configured substantially similar to the first solder ball 32, but example embodiments are not limited thereto.

The first barrier film 33 may be disposed on the side surface 31S of the first pillar bump 31. The first barrier film 33 may extend along the side surface 31S of the first pillar bump 31 and may cover or at least partially cover at least a portion of the side surface 31S of the first pillar bump 31. The first barrier film 33 may be formed of an oxide of a metal included in the first pillar bump 31. For example, the first barrier film 33 may include copper (I) oxide (Cu₂O) and copper (II) oxide (CuO). In such a case, a content of the copper (II) oxide may be greater than a content of the copper (I) oxide. The first barrier film 33 may limit a wetting region of the first solder ball 32 in the reflow process such that the height deviation of the first solder ball 32 may be reduced and shorts between (for example, related to) adjacent first solder balls 32 may be limited, reduced, or prevented.

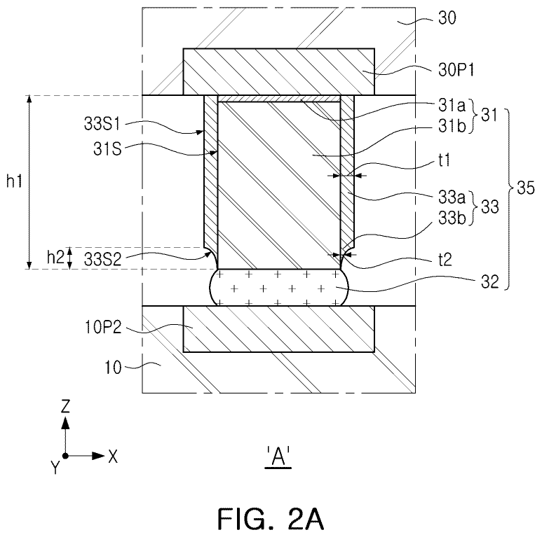

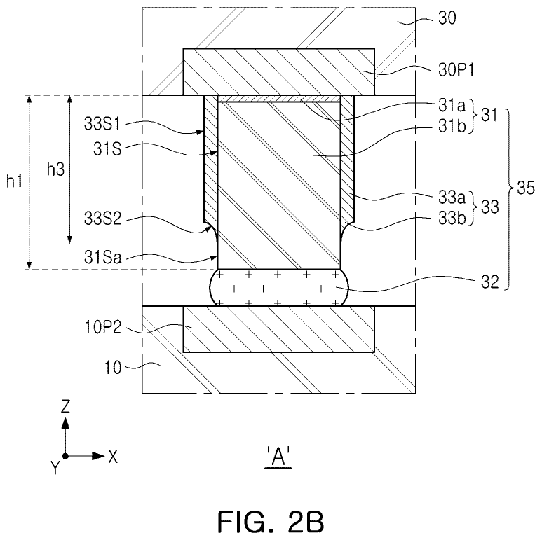

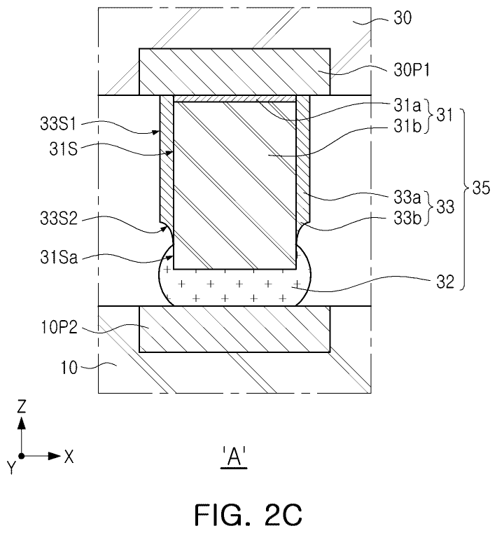

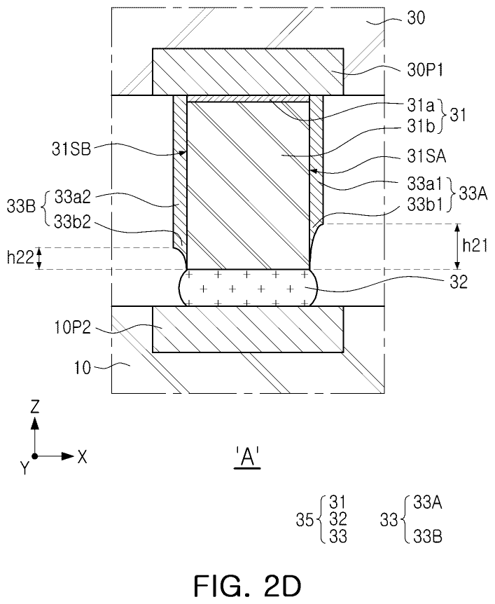

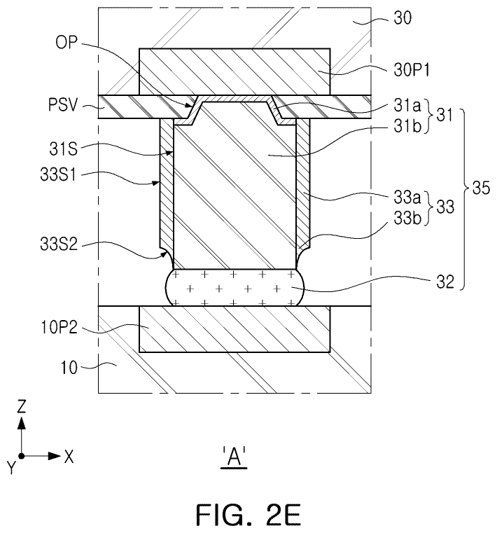

Hereinafter, the shape of the first bump structure 35 according to modified examples will be described with reference to FIGS. 2A to 2E.

FIGS. 2A to 2E are enlarged diagram illustrating region ‘A’ in FIG. 1A according to some example embodiments and modified example embodiments.

Referring to FIG. 2A, in some example embodiments, the first pillar bump 31 may include a seed layer 31a in contact with a lower terminal 30P1 of a second substrate 30 and a plating layer 31b in contact with a first solder ball 32. The plating layer 31b may be formed by an electroplating process using a seed layer 31a. For example, the seed layer 31a may include titanium (Ti) and copper (Cu), and the plating layer 31b may include copper (Cu), but example embodiments are not limited thereto.

The first barrier film 33 may have a reduced (for example, smaller) thickness in a portion adjacent to the first solder ball 32. The first barrier film 33 may include an upper region 33a (also referred to as the ‘first portion’), and a lower region 33b (also referred to as the ‘second portion’) extending from the upper region 33a and adjacent to the first solder ball 32. The upper region 33a and the lower region 33b may extend along the side surface 31S of the first pillar bump 31. The upper region 33a may have a first thickness t1 in a direction perpendicular to the side surface 31S of the first pillar bump 31. The lower region 33b may have a second thickness t2 smaller than a first thickness t1 in a direction perpendicular to the side surface 31S of the first pillar bump 31 and decreasing (for example, which decreases) toward (for example, when moving towards) the first solder ball 32. The first thickness t1 may be, for example, about 100 nm or more, but example embodiments are not limited thereto. The first thickness t1 may be, for example, determined by considering wettability of the first solder ball 32.

The lower region 33b of the first barrier film 33 may limit, reduce, or prevent wetting of the first solder ball 32 on the side surface 31S of the first pillar bump 31 while reducing contact between the first solder ball 32 and the barrier film 33. Accordingly, according to some example embodiments, the first solder ball 32 may be in contact with the lower end of the barrier film 33, such that the first solder ball 32 may be limited or prevented from spreading in the horizontal direction (X- and Y-directions) and the diameter of the first solder ball 32 may be controlled.

The upper region 33a of the first barrier film 33 may have a first side surface 33S1, and the lower region 33b of the first barrier film 33 may have a second side surface 33S2. The slope of the second side surface 33S2 with respect to the side surface 31S of the first pillar bump 31 may decrease towards (for example, when or as moving towards) the first solder ball 32. A slope of the first side surface 33S1 with respect to the side surface 31S of the first pillar bump 31 may be smaller than a slope of the second side surface 33S2. For example, the first side surface 33S1 may be parallel or substantially parallel to the side surface 31S of the first pillar bump 31.

A height of the upper region 33a in the direction parallel to the side surface 31S of the first pillar bump 31 or in the vertical direction (Z-direction) may be greater than a height of the lower region 33b. The lower region 33b may have a second height h2 of about 10% or less of the first height h1 of the first pillar bump 31 in the vertical direction (Z-direction). When the second height h2 exceeds about 10% of the first height h1, the side surface 31S of the first pillar bump 31 may be overexposed, and it may be difficult to control the wetting region of the first solder ball 32.

A height of the first barrier film 33 may be the same or substantially the same as a height h1 of the first pillar bump 31. Here, the configuration in which the height may be “substantially the same” may include a tolerance, and may be understood that the lower region 33b of the first barrier film 33 having a thickness of or ranging from, for example, at least several nm to several tens of nm extends to a lower end of the side surface 31S of the first pillar bump 31.

Referring to FIG. 2B, in some example embodiments height h3 of the first barrier film 33 may be less than the height h1 of the first pillar bump 31. At least a portion of the first pillar bump 31 may be exposed from the first barrier film 33. The side surface 31S of the first pillar bump 31 may include a lower side surface 31Sa exposed from the first barrier film 33. In this case, the height of the lower side surface 31Sa may be about 10% or less of the height h1 of the first pillar bump 31. When the height of the lower side surface 31Sa exceeds about 10% of the first height h1, the side surface 31S of the first pillar bump 31 may be excessively exposed, and it may be difficult to control the wetting region of the first solder ball 32.

Referring to FIG. 2C, in some example embodiments, the first solder ball 32 may be in contact with at least a portion of the side surface 31S of the first pillar bump 31. The side surface 31S of the first pillar bump 31 may include an upper side surface in contact with the first barrier film 33, and a lower side surface exposed from the first barrier film 33. The first solder ball 32 may be in contact with a lower surface and the lower side surface 31Sa of the first pillar bump 31. According to some example embodiments, the contact region between the first solder ball 32 and the first pillar bump 31 may be expanded such that connection reliability may be improved or ensured. Also, a size of the first solder ball 32 may be controlled or better controlled by reducing a contact region between the first solder ball 32 and the first barrier film 33.

Referring to FIG. 2D, according to some example embodiments, the first barrier film 33 may include a first barrier region 33A covering a first side surface 31SA of the first pillar bump 31, and a second barrier region 33B covering a second side surface 31SB of the first pillar bump 31. The first barrier region 33A may include a first upper region 33a1 and a first lower region 33b1. The first lower region 33b1 may have a thickness decreasing toward the first solder ball 32. The second barrier region 33B may include a second upper region 33a2 and a second lower region 33b2. The second lower region 33b2 may have a thickness decreasing toward the first solder ball 32. A height h21 of the first lower region 33b1 and a height h22 of the second lower region 33b2 may be different from each other.

Referring to FIG. 2E, the first pillar bump 31 may penetrate (for example, at least partially extend through) a passivation layer PSV and may be in contact with the lower terminal 30P1. The passivation layer PSV may include an opening OP exposing at least a portion of the lower terminal 30P1. The passivation layer PSV may be a solder resist covering a lower surface of the second substrate 30. The first pillar bump 31 may include a via portion passing through the opening OP of the passivation layer PSV.

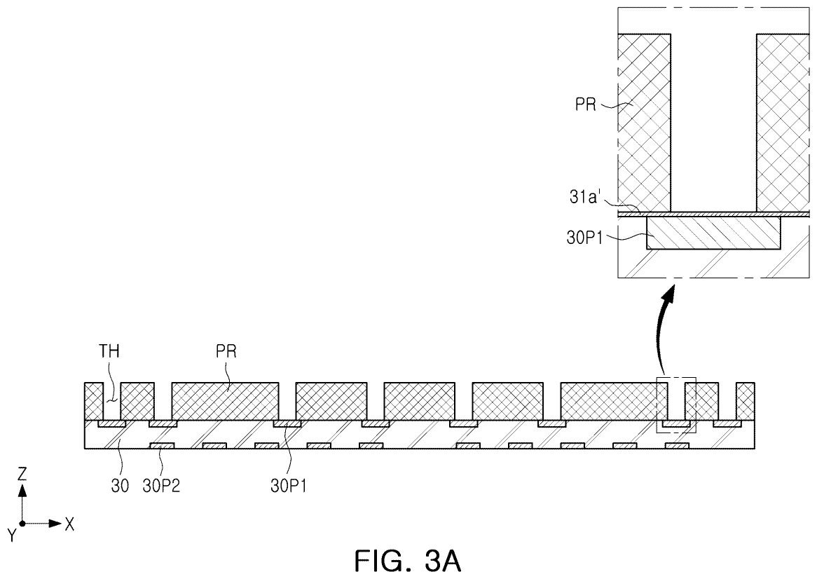

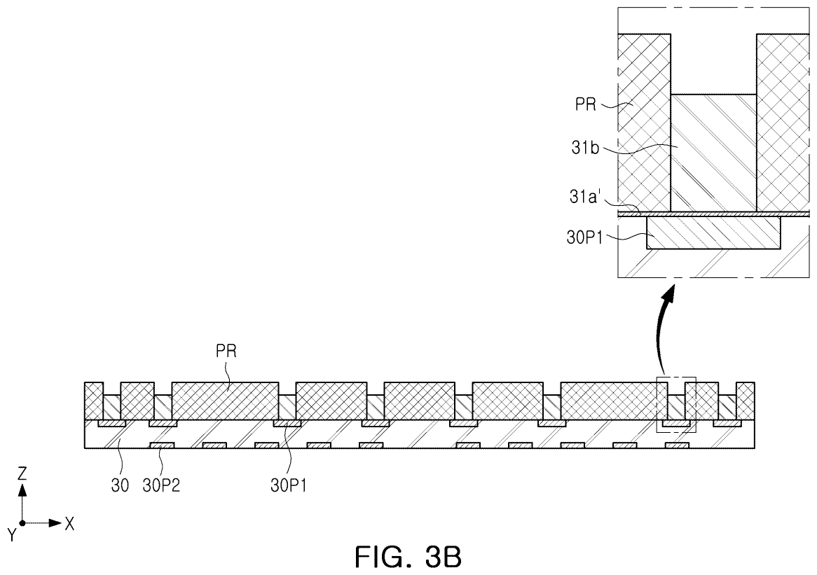

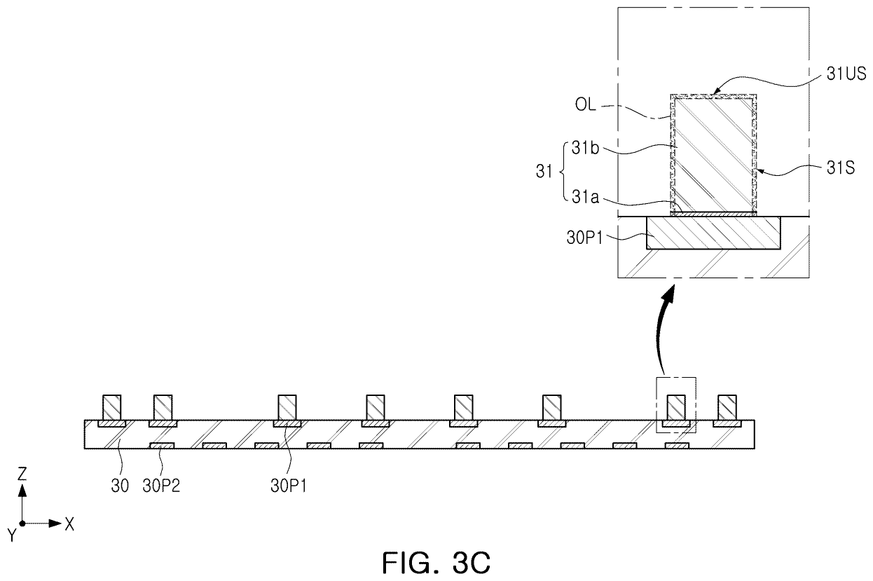

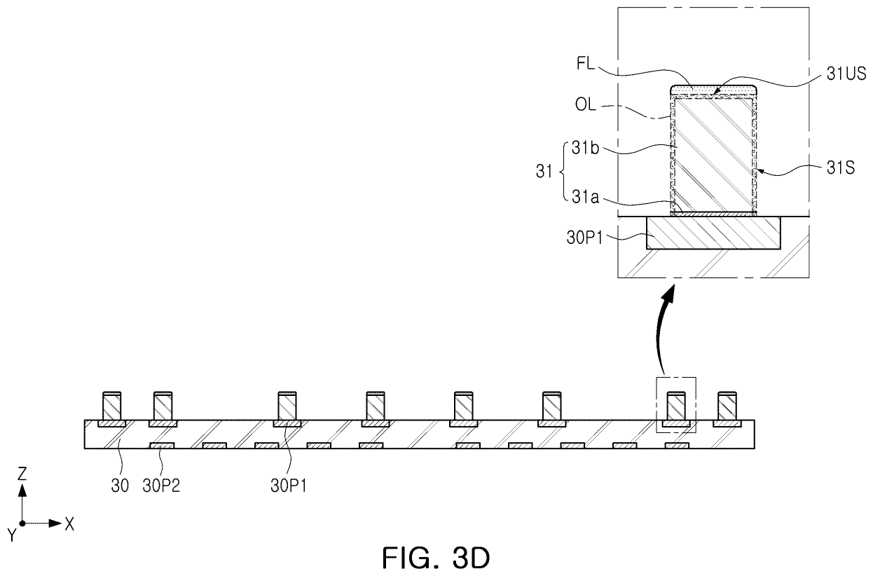

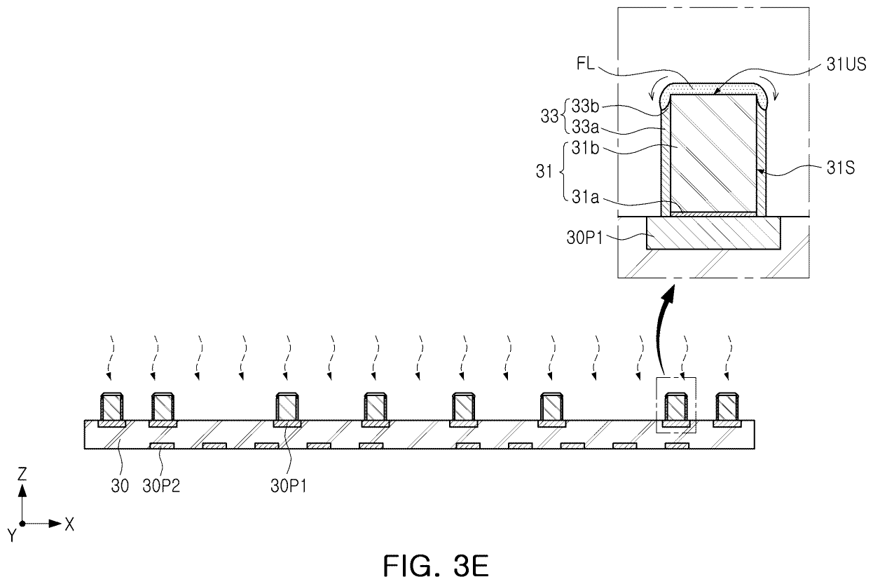

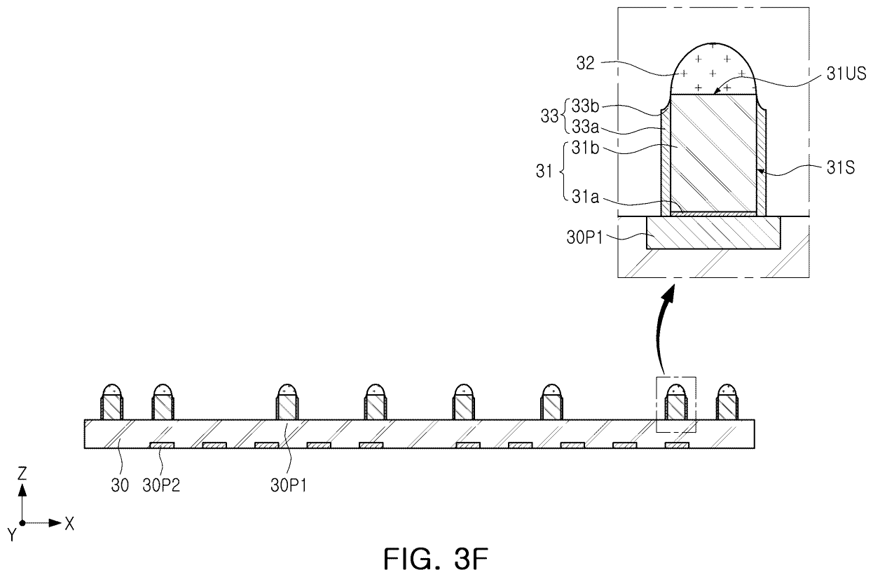

FIGS. 3A to 3F are diagrams illustrating a process of manufacturing a bump structure according to some example embodiments, for example illustrating a process of manufacturing a first bump structure 35.

Referring to FIG. 3A, a plating seed layer 31a′ and a mask pattern PR may be formed on a second substrate 30. The second substrate 30 may be configured as a wafer substrate or a panel substrate before a plurality of unit substrates are isolated. In the second substrate 30, a chip structure 20 may be mounted on the upper terminals 30P2, but the illustration thereof is not provided for ease of description. The plating seed layer 31a′ may be formed by a plating process, a physical vapor deposition (PVD) process, or a chemical vapor deposition (CVD) process, but example embodiments are not limited thereto. The plating seed layer 31a′ may include a metal such as copper (Cu) or titanium (Ti). The mask pattern PR may be formed on the plating seed layer 31a′. The mask pattern PR may include a photosensitive material. The mask pattern PR may include a through-hole TH formed by performing an exposure process, a development process, or the like. The through-hole TH may expose the lower terminals 30P1 of the second substrate 30.

Referring to FIG. 3B, a plating layer 31b may be formed in the mask pattern PR. The plating layer 31b may be formed by performing, for example, an electroplating process using a plating seed layer 31a′. The plating layer 31b may have, for example, a cylindrical or polygonal pillar shape including, for example, copper (Cu). Thereafter, the mask pattern PR may be removed by, for example, performing an ashing process.

Referring to FIG. 3C, a pillar bump 31 may be formed. The pillar bump 31 may include a seed layer 31a and a plating layer 31b. The seed layer 31a may be formed by partially etching the plating seed layer 31a′ exposed after the mask pattern PR is removed. A natural oxide film OL may be formed on the side surface 31S and the upper surface 31US of the pillar bump 31. The natural oxide film OL may be formed during the standby time of the subsequent process and may include copper (I) oxide (Cu₂O).

Referring to FIG. 3D, a flux layer FL may be formed on the pillar bump 31. The flux layer FL may be printed on an upper portion 31US of the pillar bump 31. The flux layer FL may include a material for removing a metal oxide layer. For example, the flux layer FL may include a material for removing copper oxide.

Referring to FIG. 3E, a primary reflow process may be performed. The primary reflow process may be performed at a temperature (about 200° C. or higher) at which the flux layer FL is activated and a barrier film 33 including copper (II) oxide (CuO) is formed on the surface of the pillar bump 31. During the primary reflow process, the flux layer FL may remove the natural oxide film OL of the upper surface 31US of the pillar bump 31 and may partially flow to the side surface 31S of the pillar bump 31. Flowability of the flux layer FL may be controlled by adjusting viscosity of the flux, the amount of flux printing, or the like. In the thermal atmosphere of the primary reflow process, the natural oxide film OL of the side surface 31S of the pillar bump 31 may be converted to a barrier film 33 including copper (II) oxide (CuO). Since the formation of the oxide film on an upper end of the side surface 31S of the pillar bump 31 is suppressed by the flux layer FL, the second portion 33b of the barrier film 33 may be formed.

Referring to FIG. 3F, a secondary reflow process may be performed. The secondary reflow process may be performed at a temperature (for example, about 200° C. or higher) at which the solder ball 32 melts. The solder ball 32 may be attached to the pillar bump 31 from which the flux layer FL has been removed and which may be wet throughout an entire upper portion 31US of the pillar bump 31 in the thermal atmosphere of the second reflow process.

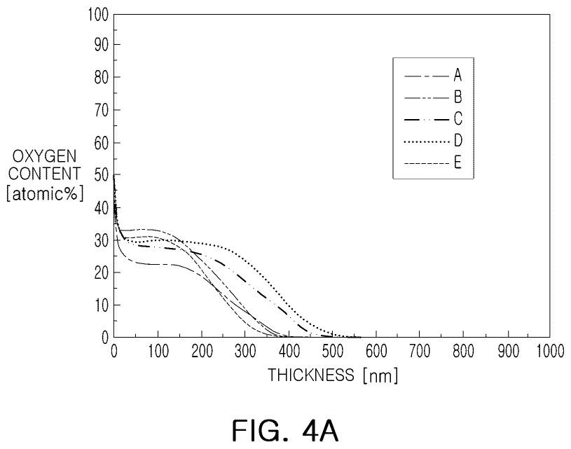

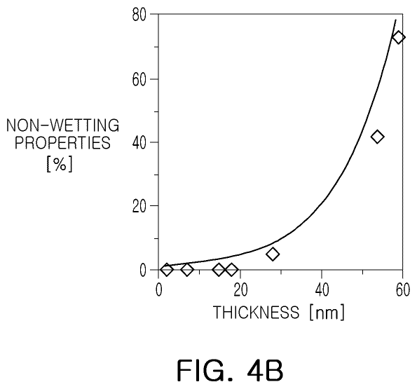

FIGS. 4A and 4B are graphs indicating characteristics of a barrier film included in a semiconductor package according to some example embodiments. FIG. 4A is a graph indicating a thickness of a copper oxide film according to the reflow time. FIG. 4B is a graph indicating the effect of improving non-wetting properties of solder depending on a thickness of the copper oxide film.

Referring to FIGS. 4A and 4B, in a process of manufacturing a bump structure in some example embodiments, by performing the primary reflow process (FIG. 3E) for an appropriate time, a barrier film having a thickness of, for example, 100 nm or more and relatively high non-wetting properties may be formed. In FIG. 4A, ‘A’ may represent a thickness of a copper oxide film formed on a surface of a pillar bump when the reflow process is performed at a temperature of about 200° C. for 1 minute. ‘B’ may represent a thickness of a copper oxide film formed on the surface of a pillar bump when the reflow process is performed at a temperature of about 200° C. for 10 minutes. ‘C’ may represent a thickness of a copper oxide film formed on the surface of a pillar bump when the reflow process is performed at a temperature of about 200° C. for 30 minutes. ‘D’ may represent a thickness of a copper oxide film formed on the surface of a pillar bump when the reflow process is performed at a temperature of about 200° C. for 120 minutes. ‘E’ may represent a thickness of the copper oxide film formed on the surface of the pillar bump when the reflow process is performed at a temperature of about 200° C. for 360 minutes.

FIG. 5 is a cross-sectional diagram illustrating a semiconductor package according to some example embodiments.

Referring to FIG. 5, a semiconductor package 1A in some example embodiments may be configured the same as or similar to the example described with reference to FIGS. 1A to 4B, other than the configuration in which the second bump structures 25 include a second barrier film 23.

The second bump structures 25 may include a second pillar bump 21, a second solder ball 22, and a second barrier film 23. The second pillar bump 21 and the second solder ball 22 may be configured the same or substantially the same as the first pillar bump 31 and first solder ball 32, and thus, an overlapping description will not be provided. The second bump structures 25 may be configured the same as or similar to the example described with reference to FIGS. 2A to 2E.

The second barrier film 23 may be disposed on a side surface of the second pillar bump 21. The second barrier film 23 may include copper (I) oxide (Cu₂O) and copper (II) oxide (CuO). A content of the copper (II) oxide may be greater than a content of the copper (I) oxide. The second barrier film 23 may limit a wetting region of the second solder ball 22 in the reflow process such that a height deviation of the second solder ball 22 may be reduced and shorts between adjacent ones of second solder balls 22 may be limited, reduced, or prevented.

The second chip structure 120b may include a plurality of semiconductor chips SC1, SC2, SC3, SC4, and SC5 and a mold layer MC. The number of the plurality of semiconductor chips SC1, SC2, SC3, SC4, and SC5 may be more or less numbers than the example illustrated in the diagram. The plurality of semiconductor chips SC1, SC2, SC3, SC4, and SC5 may be stacked in the vertical direction (Z-direction) by, for example, a thermocompression bonding method or a hybrid bonding method, but example embodiments are not limited thereto. The plurality of semiconductor chips SC1, SC2, SC3, SC4, and SC5 may be interconnected through through-silicon vias. The plurality of semiconductor chips SC1, SC2, SC3, SC4, and SC5 may include a buffer chip (e.g., SC1) and a plurality of memory chips (e.g., SC2, SC3, SC4, and SC5). The mold layer MC may include an insulating material, such as an epoxy molding compound (EMC), for example, but example embodiments are not limited thereto.

The semiconductor package 1A may further include an underfill layer UF surrounding or at least partially surrounding the second bump structures 25 on the second substrate 30, and an encapsulation layer MD covering or at least partially covering the chip structure 20. The underfill layer UF may include, for example, a thermosetting resin, such as an epoxy resin, and may be formed to encapsulate or at least partially encapsulate the second bump structures 25 by, for example, a capillary underfill (CUF) method. In some example embodiments, the underfill layer UF may be integrated with the encapsulation layer MD by a molded underfill (MUF) method. The encapsulation layer MD may include, for example, an insulating material such as EMC, but example embodiments are not limited thereto.

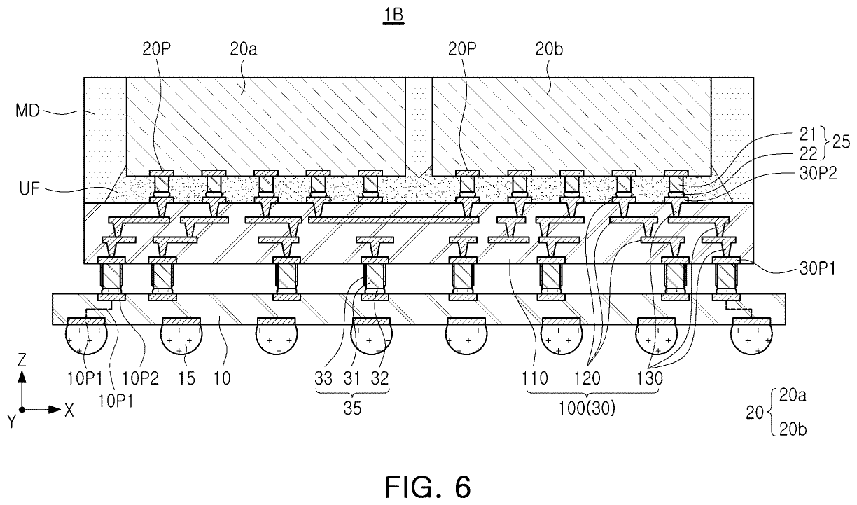

FIG. 6 is a cross-sectional diagram illustrating a semiconductor package according to some example embodiments.

Referring to FIG. 6, a semiconductor package 1B in some example embodiments may be configured the same as or similar to the example embodiments described with reference to FIGS. 1a to 5, other than the configuration in which a first type of interposer substrate 100 is included. The interposer substrate 100 may correspond to the second substrate 30 described with reference to FIG. 1A.

The interposer substrate 100 may include an insulating layer 110, a redistribution layer 120, and a redistribution via 130. The insulating layer 110 may include an insulating resin. The insulating resin may include a thermosetting resin such as, for example, an epoxy resin, a thermoplastic resin such as a polyimide, and/or a resin impregnated with an inorganic pillar, for example, a prepreg, an Ajinomoto build-up film (ABF), a FR-4, or a bismaleimide-triazine (BT), but example embodiments are not limited thereto. In some example embodiments, the insulating layer 110 may include a photosensitive resin such as a photo-imageable dielectric (PID). The insulating layer 110 may include a plurality of insulating layers stacked in the vertical direction (Z-direction). Depending on processes, a boundary between the plurality of insulating layers may or may not be distinct.

The redistribution layer 120 may be disposed on and in the insulating layer 110 and may redistribute connection pads 20P of the chip structure 120. The redistribution layer 120 may include a metal including, for example, copper (Cu), aluminum (Al), silver (Ag), tin (Sn), gold (Au), nickel (Ni), lead (Pb), titanium (Ti), or an alloy thereof. The redistribution layer 120 may perform various functions depending on design. For example, the redistribution layer 120 may include a ground pattern, a power pattern, and a signal pattern. Here, the signal pattern may be defined as a transfer path for various signals other than a ground patterns, a power pattern, or the like, such as a data signal. The number of redistribution layers included in the redistribution layer 120 may be greater or fewer than the example illustrated in the diagram.

The redistribution via 130 may extend in the insulating layer 110 and may be electrically connected to the redistribution layer 120. For example, the redistribution via 130 may interconnect redistribution layers 120 at different levels. The redistribution via 130 may include a metal material, such as, for example copper (Cu), aluminum (Al), silver (Ag), tin (Sn), gold (Au), nickel (Ni), lead (Pb), titanium (Ti), or an alloy thereof, but example embodiments are not limited thereto. The redistribution via 130 may be a filled via in which a metal material is filled in the via hole, or a conformal via in which the metal material extends along an internal wall of the via hole.

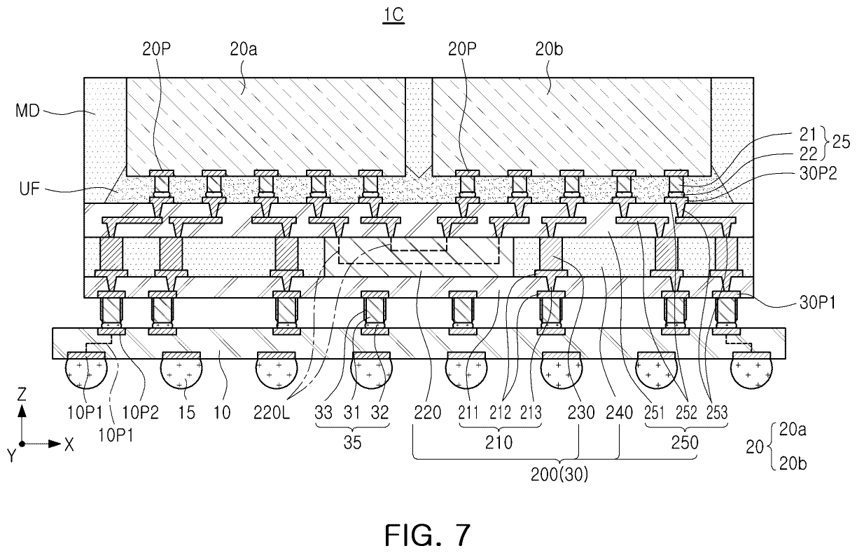

FIG. 7 is a cross-sectional diagram illustrating a semiconductor package 1C according to some example embodiments.

Referring to FIG. 7, a semiconductor package 1C in some example embodiments may be configured the same as or similar to the example described with reference to FIGS. 1a to 6, other than the configuration in which a second type of interposer substrate 200 is included. The interposer substrate 200 may correspond to the second substrate 30 described with reference to FIG. 1A. The interposer substrate 200 may include an interconnection chip 220 configured to electrically connect the chip structures 20 to each other. For example, the interposer substrate 200 may include a lower redistribution structure 210, an interconnection chip 220, through-vias 230, a mold 240, and an upper redistribution structure 250.

The lower redistribution structure 210 may include a dielectric layer 211, redistribution patterns 212, and redistribution vias 213. The dielectric layer 211 may be formed using a photosensitive resin. For example, the dielectric layer 211 may include, for example, a polyimide (PI)-based photosensitive polymer, a polybenzoxazole (PBO)-based photosensitive polymer, a polyhydroxystyrene (PHS)-based photosensitive polymer, a novolak-based photosensitive polymer, a benzocyclobutene (BCB)-based photosensitive polymer, or a photo imageable dielectric (PID).

The redistribution patterns 212 may be disposed on or in the dielectric layer 211 and may be electrically connected to the interconnection chip 220, the through-vias 230, and the chip structures 20. The redistribution patterns 212 may include, for example, copper (Cu), aluminum (Al), silver (Ag), tin (Sn), gold (Au), nickel (Ni), lead (Pb), titanium (Ti), or alloys thereof, but example embodiments are not limited thereto. The redistribution patterns 212 may include a ground pattern, a power pattern, and a signal pattern depending on design. The signal pattern may provide a transfer path for various signals (e.g., a data signal) other than a ground pattern, a power pattern, or the like. The redistribution patterns 212 may include various types of conductive lines extending in the horizontal direction (X and/or Y).

The redistribution vias 213 may penetrate the dielectric layer 211 and may be electrically connected to the redistribution patterns 212. The redistribution vias 213 may have a shape of which a side surface is tapered toward the first substrate 10. The redistribution vias 213 may include, for example, copper (Cu), aluminum (Al), silver (Ag), tin (Sn), gold (Au), nickel (Ni), lead (Pb), titanium (Ti), or alloys thereof, but example embodiments are not limited thereto. The redistribution vias 213 may be filled vias in which a metal material is filled in a via hole or conformal vias in which a metal material is formed along an internal wall of a via hole.

The interconnection chip 220 may be disposed on the lower redistribution structure 210. The interconnection chip 220 may include an interconnection circuit 220L for electrically connecting the first chip structure 20a to the second chip structure 20b. The interconnection chip 220 may be configured as a semiconductor chip in which the interconnection circuit 220L is formed on a semiconductor substrate, but example embodiments thereof are not limited thereto.

Through-vias 230 may be disposed around the interconnection chip 220 and may be electrically connected to the redistribution patterns 212. The through-vias 230 may have a post shape extending in the vertical direction (Z) corresponding to a thickness of the interconnection chip 220. One surface (e.g., upper surface) of the through-vias 230 may be coplanar with one surface (e.g., upper surface) of the mold 240 by a planarization process. The through-vias 230 may include copper (Cu), aluminum (Al), silver (Ag), tin (Sn), gold (Au), nickel (Ni), lead (Pb), titanium (Ti), or an alloy thereof, but example embodiments are not limited thereto.

The mold 240 may be disposed between the lower redistribution structure 210 and the upper redistribution structure 250. The mold 240 may be formed to encapsulate the interconnection chip 220 and the through-vias 230. The mold 240 may include, for example, a thermosetting resin such as an epoxy resin, a thermoplastic resin such as a polyimide, or a prepreg, ABF, FR-4, BT, EMC, or the like, obtained by these resins impregnated with an inorganic pillar, but example embodiments are not limited thereto.

The upper redistribution structure 250 may include an upper dielectric layer 251, an upper redistribution patterns 252, and upper redistribution vias 253. The upper dielectric layer 251, the upper redistribution patterns 252, and the upper redistribution vias 253 may be configured substantially the same as the dielectric layer 211, the redistribution patterns 212, and the redistribution vias 213 described above, and thus, an overlapping description will not be provided. The upper redistribution patterns 252 may be connected to the interconnection circuit 220L through upper redistribution vias 253. The chip structures 20 may be electrically connected to the interconnection chip 220 through the upper redistribution patterns 252.

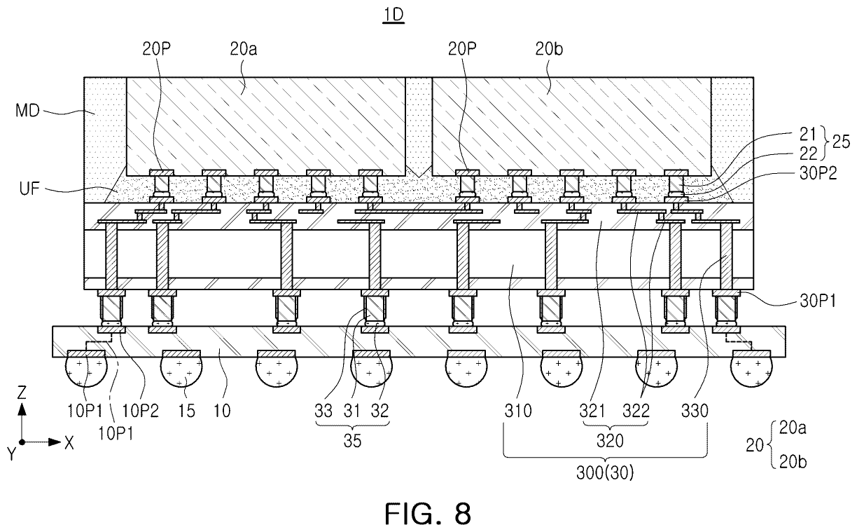

FIG. 8 is a cross-sectional diagram illustrating a semiconductor package 1D according to some example embodiments.

Referring to FIG. 8, a semiconductor package 1D in some example embodiments may be configured the same as or similar to the example described with reference to FIGS. 1a to 7, other than the configuration in which a third type of interposer substrate 300 is included. The interposer substrate 300 may correspond to the second substrate 30 described with reference to FIG. 1A.

The interposer substrate 300 may include a substrate 310, an interconnection structure 320, and a through-electrode 330. The chip structures 20 may be electrically connected to each other through the interposer substrate 300.

The substrate 310 may be formed of or include, for example, at least one of a silicon, an organic, a plastic, or a glass substrate. When the substrate 310 is, for example, configured as or include a silicon substrate, the interposer substrate 300 may be referred to as a silicon interposer. An insulating film surrounding lower portions of the through-electrodes 330 may be formed between the substrate 310 and the lower terminals 30P1.

The interconnection structure 320 may be disposed on the substrate 310 and may include an insulating layer 321 and a single-layer or multilayer interconnection structure 322. When the interconnection structure 320 is formed of a multilayer interconnection structure, interconnection patterns on different layers may be connected to each other through contact vias.

The through-electrode 330 may penetrate (for example, at least partially extend though) the substrate 310 and may electrically connect the lower terminals 30P1 to the upper terminals 30P2. When the substrate 310 is, for example, configured as or includes a silicon substrate, the through-electrode 330 may be referred to as a TSV.

In some example embodiments, the interposer substrate 300 may be used to convert or transfer an input electrical signal between the chip structures 20. The interposer substrate 300 may or may not include devices such as an active device or a passive device.

According to at least the aforementioned example embodiments, by including bump structures in which a height deviation of the solder ball is controlled, a semiconductor package having improved reliability may be provided.

While various example embodiments have been illustrated and described above, it will be configured as apparent to those ordinarily skilled in the art that modifications and variations could be made without departing from the spirit and scope of the inventive concepts as defined by the appended claims.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A semiconductor package, comprising:
a first substrate including upper pads and lower pads, the upper pads and lower pads opposite to each other, the first substrate including a first redistribution circuit electrically connecting the upper pads to the lower pads;
a second substrate on the first substrate and including upper terminals and lower terminals, the upper terminals and lower terminals opposite to each other, the second substrate including a second redistribution circuit connecting the upper terminals to the lower terminals;
at least one chip structure on the second substrate and including connection pads;
connection bumps below the first substrate;
first bump structures between the first substrate and the second substrate and electrically connecting the upper pads of the first substrate to the lower terminals of the second substrate; and
second bump structures between the at least one chip structure and the second substrate and electrically connecting the upper terminals of the second substrate to the connection pads of the at least one chip structure,
wherein each of at least some of the first bump structures and the second bump structures includes
a pillar bump in contact with one of the lower terminals or with the connection pads,
a solder ball connecting the pillar bump to one of the upper pads or the upper terminals, and
a barrier film at least partially covering a side surface of the pillar bump, and
wherein a thickness of the barrier film decreases in a direction perpendicular to the side surface of the pillar bump in a portion that is adjacent to the solder ball.

2. The semiconductor package of claim 1, wherein
the barrier film includes an upper region and a lower region, the lower region extending from the upper region and adjacent to the solder ball,
the upper region has a first thickness,
the lower region has a second thickness, and
the second thickness is smaller than the first thickness and decreases towards the solder ball.

3. The semiconductor package of claim 2, wherein a height of the upper region is greater than a height of the lower region in a direction parallel to the side surface of the pillar bump.

4. The semiconductor package of claim 2, wherein the lower region has a height of 10% or less of a height of the pillar bump in a direction parallel to the side surface of the pillar bump.

5. The semiconductor package of claim 2, wherein the first thickness is 100 nm or more.

6. The semiconductor package of claim 1, wherein a height of the barrier film is equal to or less than a height of the pillar bump in a direction parallel to the side surface of the pillar bump.

7. The semiconductor package of claim 6, wherein
a height of the barrier film is smaller than a height of the pillar bump, and
the side surface of the pillar bump includes a lower side surface exposed from the barrier film.

8. The semiconductor package of claim 7, wherein a height of the lower side surface is 10% or less of a height of the pillar bump.

9. The semiconductor package of claim 1, wherein
the barrier film includes a first barrier region at least partially covering a first side surface of the pillar bump, and a second barrier region at least partially covering a second side surface of the pillar bump,
the first barrier region includes a first lower region of which a thickness decreases towards the solder ball,
the second barrier region includes a second lower region of which a thickness decreases towards the solder ball, and
the first lower region and the second lower region have different heights.

10. The semiconductor package of claim 1, wherein the barrier film includes copper (I) oxide (Cu₂O) and copper (II) oxide (CuO).

11. The semiconductor package of claim 10, wherein a content of copper (II) oxide is greater than a content of copper (I) oxide.

12. The semiconductor package of claim 1, wherein each of a minimum distance between the first bump structures and a minimum distance between the second bump structures is less than a minimum distance between the connection bumps.

13. The semiconductor package of claim 12, wherein each of the minimum distance between the first bump structures and the minimum distance between the second bump structures is 100 μm or less.

14. The semiconductor package of claim 1, wherein
the at least one chip structure is in the form of a plurality of chip structures that are on the second substrate, and
the plurality of chip structures are interconnected through the second redistribution circuit.

15. The semiconductor package of claim 14, wherein
the plurality of chip structures includes a first chip structure and a second chip structure,
the first chip structure includes a logic chip, and
the second chip structure includes a memory chip.

16. The semiconductor package of claim 1, further comprising:
an encapsulation layer on the second substrate and at least partially covering the at least one chip structure.

17. A semiconductor package, comprising:
a first substrate including a first redistribution circuit;
a second substrate on the first substrate and including a second redistribution circuit;
at least one chip structure on the second substrate and including connection pads;
first bump structures between the first substrate and the second substrate and electrically connecting the first redistribution circuit to the second redistribution circuit; and
second bump structures between the at least one chip structure and the second substrate and electrically connecting the second redistribution circuit to the connection pads,
wherein each of at least some of the first bump structures and each of at least some of the second bump structures includes
a pillar bump,
a solder ball on a lower surface of the pillar bump,
and a barrier film on a side surface of the pillar bump,
wherein the side surface of the pillar bump includes an upper side surface and a lower side surface, the upper side surface in contact with the barrier film, the lower side surface exposed from the barrier film, and
wherein the solder ball is in contact with the lower surface of the pillar bump and with the lower side surface of the pillar bump.

18. The semiconductor package of claim 17, wherein
the pillar bump includes a metal, and
the barrier film includes an oxide of the metal.

19. A semiconductor package, comprising:
a first substrate including a first redistribution circuit;
a second substrate on the first substrate and including a second redistribution circuit;
at least one chip structure on the second substrate and including connection pads;
first bump structures between the first substrate and the second substrate and electrically connecting the first redistribution circuit to the second redistribution circuit; and
second bump structures between the at least one chip structure and the second substrate and electrically connecting the second redistribution circuit to the connection pads,
wherein each of at least some of the first bump structures and each of at least some of the second bump structures includes
a pillar bump,
a solder ball at least partially covering a lower surface of the pillar bump,
and a barrier film at least partially covering a side surface of the pillar bump,
wherein the barrier film includes a first portion and a second portion, the first portion having a first side surface extending along the side surface of the pillar bump, the second portion having a second side surface extending from the first side surface to the side surface of the pillar bump, and
wherein a slope of the second side surface with respect to the side surface of the pillar bump decreases towards the solder ball.

20. The semiconductor package of claim 19, wherein a slope of the first side surface with respect to the side surface of the pillar bump is smaller than the slope of the second side surface with respect to the side surface of the pillar bump.
